(19) United States
(12) Patent Application Publication
(10) Pub. No.: US 2013/0039787 A1
(43) Pub. Date: Feb. 14, 2013

(54) ENERGY TRANSFER FLUID DIAPHRAGM AND DEVICE

(71) Applicant: Timothy S. Lucas, Richmond, VA (US)

(72) Inventor: Timothy S. Lucas, Richmond, VA (US)

(73) Assignee: Influent Corporation, Ashland, VA (US)

(21) Appl. No.: 13/576,836

(22) PCT Filed: Jan. 25, 2011
(86) PCT No.: PCT/US11/22386

§ 371 Date: Oct. 29, 2012

Related U.S. Application Data
(60) Provisional application No. 61/301,599, filed on Feb. 4, 2010.

(51) Int. Cl. F04B 45/047; H01L 41/04

(52) U.S. Cl. 417/413.1; 310/330

(57) ABSTRACT

An energy transfer fluid diaphragm including a diaphragm substrate including cutouts. The cutouts are covered with a sealing layer bonded to the diaphragm substrate. The cutouts are configured to bend thereby allowing displacement of a center portion of the diaphragm. The displacement of the center portion transfers energy to a fluid located adjacent to the diaphragm.

### CROSS-REFERENCE TO RELATED APPLICATIONS

This application claims priority to and the benefit of U.S. Provisional Application No. 61/301599, filed Feb. 4, 2010 (incorporated by reference herein in its entirety).

### BACKGROUND

This application relates generally to positive displacement diaphragms for conveying energy to fluids within fluid moving devices (FMDs) such as liquid pumps, compressors, vacuum pumps and synthetic jets and also relates to the use of noise cancellation for reducing the noise of high-velocity synthetic jets.

When compared to rotary, piston, centrifugal and other pumping approaches, diaphragms provide a lower profile means for creating a cyclic positive displacement for small FMDs. Smaller or miniature FMDs may be compared using pumping power density as defined by pumping power divided by the FMD size. An increase IN pumping power requires an increase in either displacement per stroke or pressure lift or both. A common limitation of diaphragms is that they do not provide large volumetric displacements due to their small strokes which are impaired by the stress limits of the diaphragm materials such as metals or plastics. If more elastic materials such as common elastomers are used that permit larger strokes, then the diaphragm will typically flex or “balloon” during a stroke in response to increasing pressure thus preventing larger pressure lifts and preventing higher power densities.

High power synthetic jets are one type of miniature FMDs that may employ diaphragms. One particular issue related to diaphragms used in miniature FMDs pertains to high power synthetic jets. Synthetic jets can provide significant energy savings when used for cooling high power density and high power dissipation electronics products such as for example servers, computers, routers, laptops, HBLEDs and military electronics. However, the compression chamber of a synthetic jet actuator must accommodate large displacement strokes creating high dynamic pressures in order to drive large multi-port manifolds while, at the same time, the actuator must be small enough to fit within many space constrained products. Conventional diaphragm technologies that are stiff enough to create large pressures cannot provide the required displacement to drive multi-port manifolds. Elastomeric diaphragms that are flexible enough to provide large displacements cannot create high dynamic pressures.

There is, therefore, a need for diaphragms for use in positive displacement FMDs that can provide large axial strokes but, at the same time, are stiff enough to create large dynamic pressures, thereby enabling increased pumping power density for miniature FMDs.

Cooling high heat dissipation electronics in space constrained products typically requires synthetic jets providing either high jet exit velocities from multiple actuator ports or multiple manifold ports that provide direct jet impingement to the hot devices within the product. However, the periodic port pressures and air velocities emanating from high-power synthetic jet ports can create significant sound levels at the drive frequency. Higher air velocities result in higher sound levels, which can result in unacceptable noise levels for a given product. As a result, a cooling capacity limit may be imposed on a synthetic jet system in order to provide for acceptable noise levels and quiet operation. Further, in order to achieve the power density required to create the high exit port velocities in a small actuator package, large actuator forces are required to create the requisite high dynamic pressures, which can lead to unacceptable vibration levels for a given product. There is, therefore, a need for synthetic jet systems that provide high jet velocities through multiple ports with low vibration and low noise levels to enable energy savings in electronics products.

### SUMMARY

The present applications discloses a diaphragm including materials such as metals, plastics or other composites and having cutouts that enable large displacements and an over molded layer that seals the cut outs to provide a pressure-tight diaphragm. The disclosed diaphragm overcomes the limitations of previous fluid moving devices and diaphragm technologies. The performance of small FMDs is often improved by taking advantage of a system mass-spring mechanical resonance which provides higher diaphragm displacements at reduced actuator forces and resulting reduced actuator sizes. The primary mechanical spring that sets the system resonance in conventional FMDs is typically a separate component from the diaphragm. To further satisfy the need for higher pumping power density the diaphragm disclosed herein provides for the integration of these two components, the system spring and diaphragm, into a single component which reduces the number of parts needed and enables a lower profile miniature FMD package.

The present application also discloses a synthetic jet system that overcomes the limitations of conventional high velocity synthetic jets systems by providing oppositely phased jet ports that are driven by separate compression chambers having pumping cycles that are 180° out phase. The synthetic jet system is configured so that the pulsations emanating from at least two oppositely phased ports, or a plurality of oppositely phased ports, provide sound cancelation resulting in lower sound levels especially for acoustic energy at the actuator drive frequency. Further, the disclosed synthetic jet system provides two pistons that move in opposition thereby canceling each other's reaction forces on the actuator body, thereby overcoming the limitations associated with excessive vibration.

### BRIEF DESCRIPTION OF THE DRAWINGS

The accompanying drawings, which are incorporated in and form a part of the specification, illustrate select embodiments of the present invention and, together with the description, serve to explain the principles of the inventions. In the drawings:

FIG. 1 provides an example of a diaphragm with cutouts to reduce the degree of material stress per axial displacement resulting in larger axial displacements and lower axial spring stiffness;

FIG. 2 illustrates another example of a diaphragm with cutouts to reduce the degree of material stress per axial displacement resulting in larger axial displacements and lower axial spring stiffness;

FIG. 3 illustrates a further example of a diaphragm with cutouts to reduce the degree of material stress per axial displacement resulting in larger axial displacements and lower axial spring stiffness;

FIG. 4 illustrates a high displacement diaphragm with a single bonded elastic layer to provide a pressure seal;

FIG. 5 illustrates a high displacement diaphragm with a bonded elastic layer on both sides of the diaphragm to provide a pressure seal;

FIG. 6 illustrates a synthetic jet system having two manifolds connected respectively to two separate compression chambers of opposite phase to provide noise cancelation between the ports of the two manifolds;

FIG. 7 illustrates a 2-diaphragm synthetic jet system having three compression chambers with one manifold connected to the center compression chamber and the other manifold connected to the two outer compression chambers which have a pumping phase opposite to the center compression chamber, to provide noise cancelation between the ports of the two manifolds and further to provide actuator vibration cancelation;

FIG. 8 illustrates a low profile actuator comprising the diaphragms of the present invention in combination with an electro active material to form a bender actuator that oscillates the diaphragm for providing fluidic energy transfer;

FIG. 9 shows the addition of a reaction mass to the bender actuator of FIG. 8 thereby improving power transfer to the diaphragm;

FIG. 10 illustrates an embodiment of a diaphragm being used as the positive displacement element in a FMD;

FIG. 11 illustrates an exemplary embodiment of a diaphragm arranged in a non axi-symmetric configuration, which enables new FMD form factors;

FIG. 12A shows a top view of diaphragm substrate;

FIG. 12B shows the FEA calculated bending mode of the FIG. 12A diaphragm;

FIG. 13A shows a top view of diaphragm substrate;

FIG. 13B shows the FEA calculated bending mode of the FIG. 13A diaphragm;

FIG. 14 illustrates the FEA calculated bending mode of a spring with two spring rows;

FIG. 15 illustrates the FEA calculated bending mode of a spring with four spring rows;

FIG. 16 illustrates the FEA calculated bending mode of a spring with eight spring rows;

FIG. 17 illustrates the FEA calculated bending mode of a spring with four spring rows;

FIG. 18 shows how the bending mode of the FIG. 17 spring changes with spring leg aspect ratio.

### DETAILED DESCRIPTION

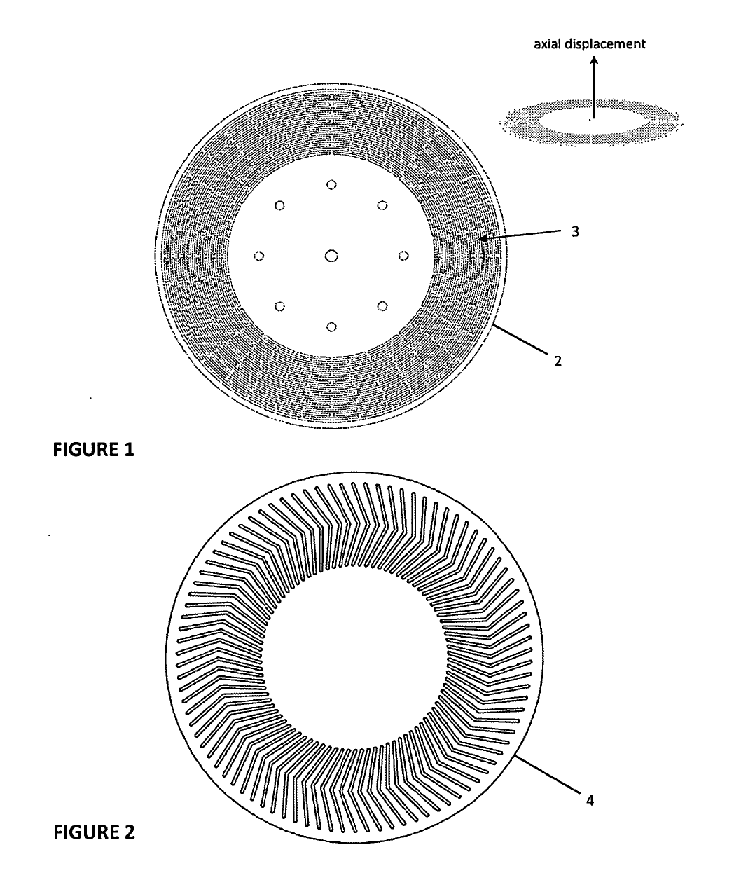

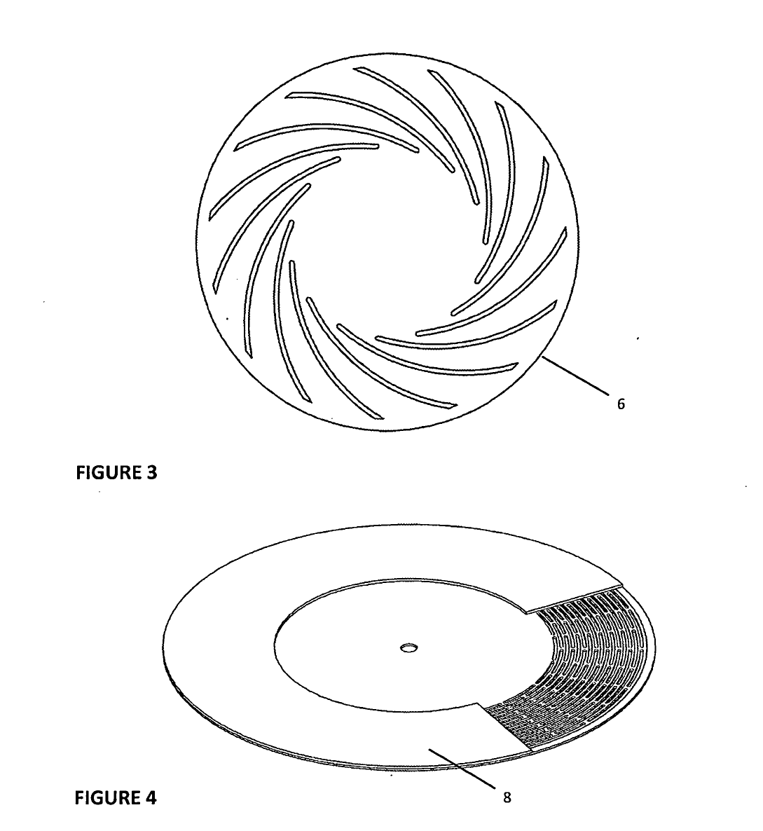

Diaphragms 2, 4 and 6 of respective FIGS. 1, 2 and 3 provide examples of diaphragms substrates that may be used in FMDs such as pumps, compressors, vacuum pumps and synthetic jets. Like other diaphragms, the disclosed diaphragms may be rigidly clamped around their outer perimeter into a FMD housing with the remainder of the diaphragm free to move axially in response to an applied motor force. Diaphragms of the present invention may be used with any motor that applies a cyclic force to the diaphragm such as rotary motors driving eccentrics or crankshafts, wobble piston FMDs or any number of linear motors that directly generate a periodic axial force. The diaphragm has a cutout pattern that reduces the bending stresses resulting from axial displacements, enabling larger axial displacements than a simple disk diaphragm without cutouts. The portion or segments (i.e., “legs”) of the diaphragm created by these cutout patterns act as springs and taken together form a spring network or spring matrix. Diaphragm substrates may be constructed from a number of materials including metals, plastics and fiber reinforced plastics to name a few. It will be clear to one skilled in the art that the specific spring matrix pattern chosen as well as its specific cutout dimensions may be used to provide design specifications such as target stresses, axial spring stiffness and the fluidic volumetric displacement resulting from a given axial center diaphragm displacement. For example, in diaphragm substrate 2 of FIG. 1, the number of annular spring rows, annular springs per row and the spring leg cross sectional aspect ratio (i.e. radial thickness of a spring leg vs. the axial thickness of a spring leg) that comprise the spring matrix area 3, may be varied or adjusted to create the desired diaphragm characteristics of a given application. The cutout dimensions may also be chosen so as to control whether the spring stiffness is linear or nonlinear. It will also be clear to one skilled in the art that there are a great number of different cutout patterns that may be used within the scope of the present invention. For example, the diaphragm cut out patterns could employ any number of different designs and need not adhere to a particular symmetry. The ability to design a diaphragm to have a particular spring constant allows the diaphragm to serve as the system spring, or resonant frequency determining spring, in a mechanically resonant FMD. Thus, the present invention integrates the diaphragm and system resonance spring into a single component.

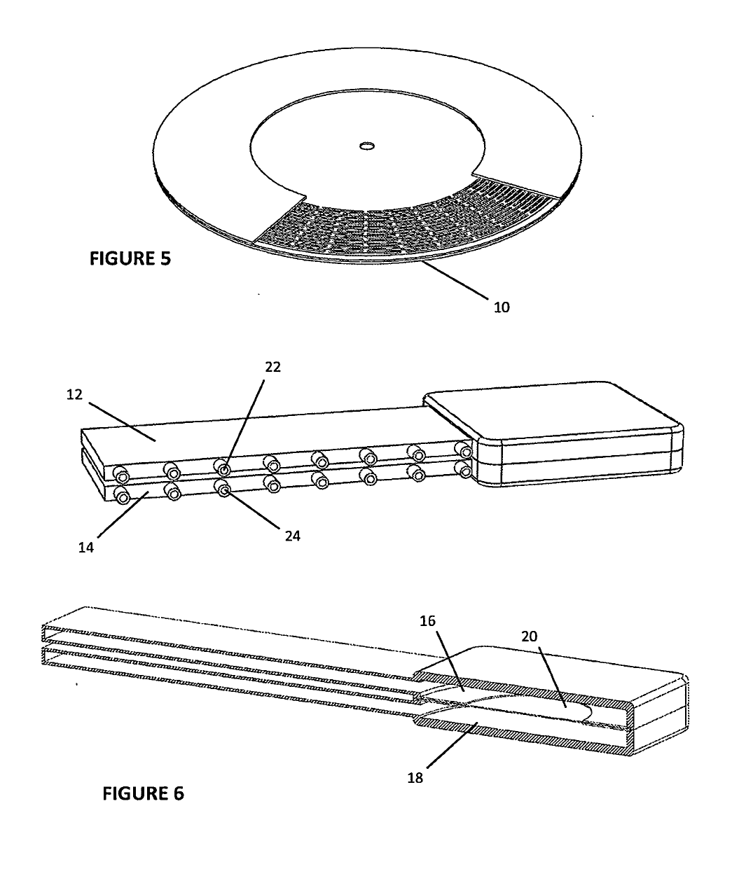

In order to use the diaphragms of the present invention in a fluid mover, a pressure seal must be provided for the spring matrix. FIG. 4 shows a sealing layer 8 that provides a pressure seal for the spring matrix with sealing layer 8 being cut away for illustration purposes. The sealing layer will typically have greater elasticity than the diaphragm substrate to provide a seal but also allow flexing of the diaphragm cutout pattern. FIG. 5 shows a second sealing layer 10 bonded to the bottom of the diaphragm. Sealing layers may be attached to the diaphragm substrate in a number of ways including adhesive bonding. Another approach, referred to as over-molding, typically involves placing the diaphragm substrate in an injection mold and injecting the sealing material in a liquid state into the mold which solidifies into the sealing layer. The advantage of injection molding is that the sealing material will flow through the spring matrix cut outs prior to solidifying and thereby bonding the two sealing layers together through the spring matrix. The sealing layer may comprise any number of materials such as EPDM or other elastomeric materials or any substance that can seal the diaphragm substrate without preventing the flexing of the cutout pattern.

FIG. 10, illustrates how a diaphragm of the present invention may be used as the fluid moving element, or positive displacement element, of a FMD such as a pump, compressor, vacuum pump or synthetic jet. In FIG. 10, the FMD 66 has a fluid chamber 58 bounded by a housing 64 and a diaphragm 56. Half of the over molding of the diaphragm 56 is cut away to show the spring matrix detail. Ingress of fluid (i.e. gas or liquid or mixed phase) is provided for by an inlet 60 and egress of fluid is provided for by an outlet 62. In operation, a motor displaces the diaphragm 56 and the resulting axial diaphragm displacement creates in a change in the volume of the fluid chamber 58 thereby transferring energy to the fluid within the fluid chamber 58.

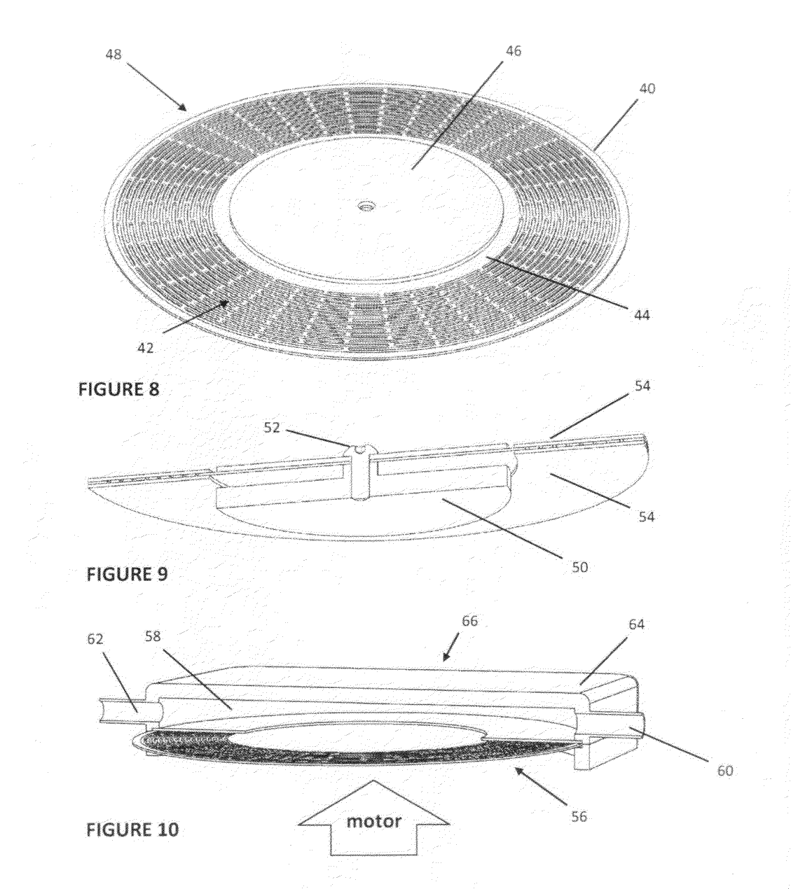

Any number of motors may be used to actuate the diaphragm of FIG. 10 within the scope of the present invention and such motors could include a rotary motor with a concentric (or other suitable device) for converting rotary motion into oscillatory motion of the diaphragm; linear electromagnetic motors such as variable reluctance or solenoid type motors; or a motor employing electroactive materials such as the bender piezo actuator of FIGS. 8 and 9 or a motor comprising single or stacked piezo elements. Depending on the type of fluid mover, the inlet 60 and the outlet 62 may be provided with valves and valve plenums as in the case of liquid pumps, gas compressors or vacuum pumps or may instead serve as jet ports in the case of synthetic jets and also in the case of synthetic jets only one jet port may be used or any number of jet ports may be used simultaneously. The diaphragm may be driven in a planar mode, where the diaphragm center plane remains substantially transverse to the displacement axis throughout the stroke. Alternatively, the diaphragm could be used on a so-called wobble-piston pump, compressor or vacuum pump, where the diaphragm is driven by a concentric such that the center surface of the diaphragm does not remain transverse to the displacement axis during the stroke, but instead wobbles cyclically throughout the stoke.

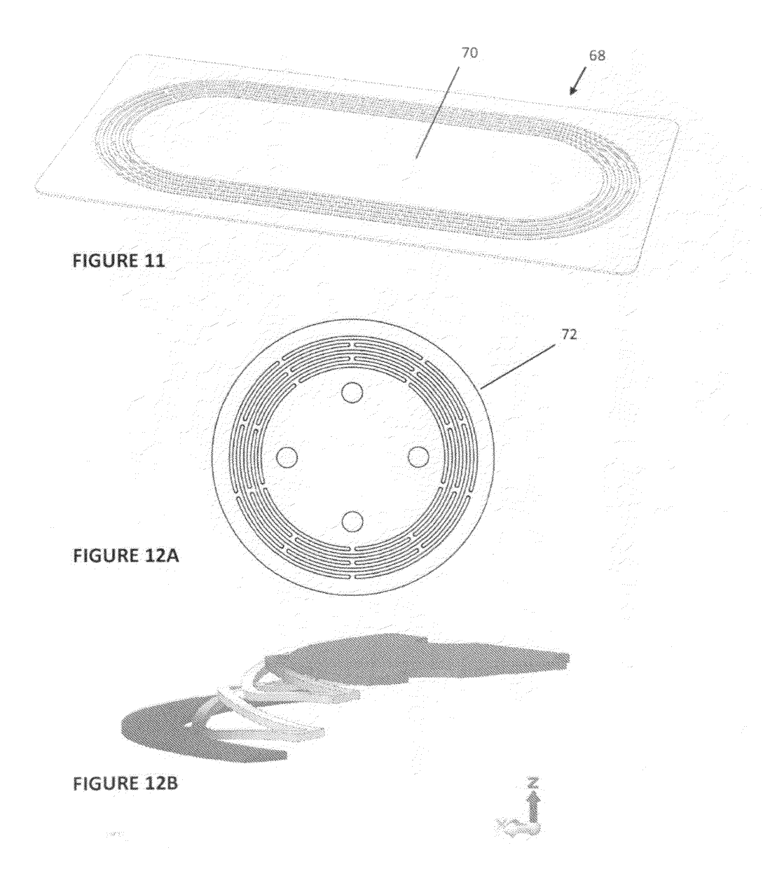

The diaphragm embodiments of the present invention need not be round or axi-symmetric but can also be rectangular, elliptical or any other shape that is well matched to a given application. This is a significant advantage of the diaphragms of the present invention in that they enable unconventional FMD topologies and form factors. FIG. 11 illustrates a non axi-symmetric diaphragm 68 that provides the same advantages as the diaphragm of FIG. 1. Sealing layers or over molding may be used to create a pressure seal across the spring matrix areas. In operation, the perimeter of the diaphragm 68 would be clamped into a FMD housing and the center area 70 would be displaced by a motor/actuator to provide energy transfer to the fluid. It will occur to one skilled in the art that non axi-symmetric diaphragms enable the design of FMDs having a wide variety of form factors that may be designed specifically to accommodate the available space in a given end product and such variations are considered within the scope of the present invention.

Fabrication methods for metal diaphragm substrates include chemical etching, stamping and laser or water jet cutting and fabrication methods for plastic diaphragm substrates include stamping and injection molding.

The diaphragm substrates of the present invention may be designed to handle the large axial displacements and pressures needed to increase the pumping power density of FMD diaphragms. The ability of the diaphragm to meet the performance requirements depends, in part, on the pressure seal provided by the over molding material. However, if the advantages of the high-stroke high-pressure diaphragms of the present invention are to be realized, then the over molding material must be added in such as way that it does not interfere with diaphragm or FMD performance. Specifically the over molding challenges that must be overcome include (1) providing long over molding material life, (2) the difficulty of designing a target spring constant into the diaphragm due to interactions between the molding material and the spring matrix and (3) poor FMD energy efficiency due to high diaphragm damping caused by interactions between the molding material and the spring matrix.

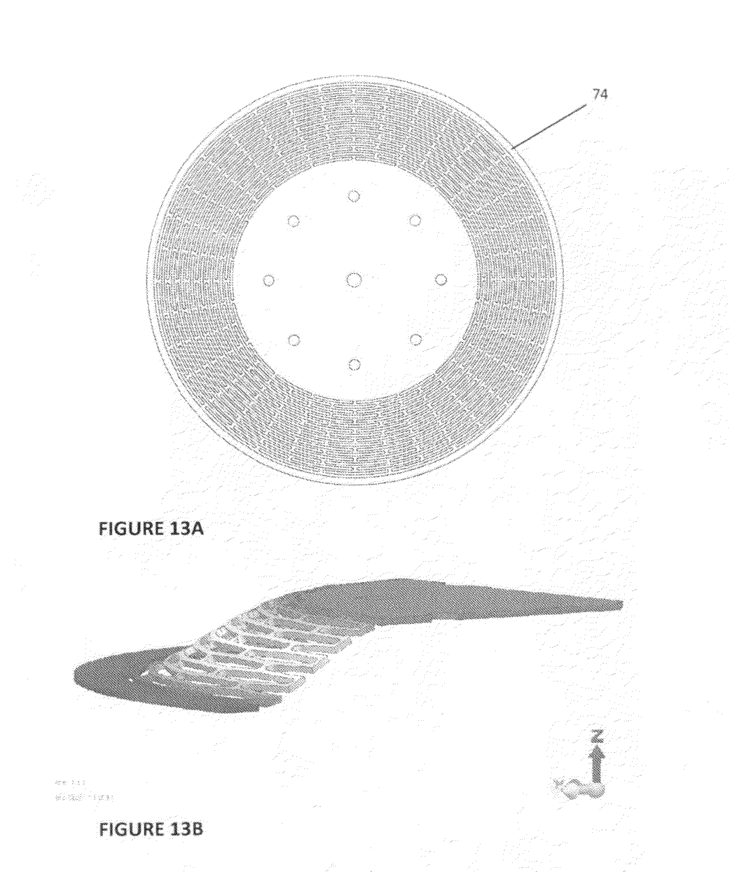

A diaphragm substrate of the present invention may be designed for so-called infinite life by designing the spring matrix so that the individual spring legs are only subjected to stress corresponding to a small fraction of the bending stress limits for the legs. Another failure mode considered during design of the diaphragm is a compromised pressure seal due to failure of the over molding material. To avoid over molding failure, the over molding stretch required for a given diaphragm displacement should be minimized and local stretch concentrations should be avoided in favor of a uniform stretch over the spring matrix area. For diaphragm applications requiring large displacements and long over molding life, the present invention introduces a planar bending mode of the individual spring matrix members as illustrated in FIGS. 12-13 in order to reduce over molding stretch and reduce local stretch concentrations.

FIG. 12A shows a diaphragm 72 having a spring matrix with 4 annular spring rows and 5 springs per annular row. FIG. 12B provides the finite element analysis (FEA) calculated deflection mode shape of a ¼ wedge of the diaphragm 72 showing that the principal bending direction of the individual spring legs is axial (i.e. in the direction of the diaphragm displacement). The axial distance between the deflected spring rows, starting from the diaphragm perimeter and proceeding towards the diaphragm center creates a stair step effect which would clearly not result in a uniform over molding stretch over the spring matrix, but instead creates a stair step effect that would concentrate the over molding stretch in the regions between the stair steps.

FIG. 13A shows a diaphragm 74 having a spring matrix with 15 annular spring rows and 18 springs per annular row. FIG. 13B provides the FEA calculated deflection mode shape of a ¼ wedge of the diaphragm 74 showing that the principal bending direction of the individual spring legs remains in the plane of the spring matrix, rather than producing the stair step effect of the diaphragm in FIG. 12B. The planar bending mode of FIG. 13B minimizes the local stretch concentrations and provides a more uniform stretch of the over molding material over the spring matrix, thereby promoting long over molding material life.

In order for the diaphragm to enable resonant FMD operation, the diaphragm should serve as the system resonance spring and provide the target spring stiffness for a given design while also providing a low damping constant. If the damping is high, then no energy may be stored in the mechanical resonance and, also, energy efficiency will be reduced due to excessive damping losses. Unless the diaphragm bends principally in a planar mode, the over molding material will significantly increase the net spring stiffness and damping of the diaphragm. If the bending mode is principally axial, as shown in FIG. 12B, then the application of the over molding material will dramatically increase both the diaphragm spring stiffness as well as the diaphragm damping constant, resulting in an “over damped” condition for the FMD's mass-spring resonance. In the over damped condition, the advantages of resonant operation are not achieved, since no energy will stored in the resonance, and, also, the energy consumption of the FMD will be increased due to the increased diaphragm damping energy dissipation. Multiple order of magnitude increases in stiffness and damping can occur when applying over molding to an axial bending spring like, for example, the diaphragm shown in FIG. 12B and these high damping values can increase FMD energy consumption by a factor of 10 making high-pressure high-stroke diaphragms impractical. Further, quiet operation is imperative for most small FMD applications and the increased spring stiffness resulting from over molding an axial bending diaphragm, can prevent the spring stiffness from being low enough to enable resonant operation at the low frequencies required to meet FMD acoustic noise level requirements.

Planar bending diaphragms, like the diaphragm 74 of FIG. 13A, solve the above diaphragm life, stiffness-frequency-noise and damping-energy issues by minimizing interactions between the diaphragm substrate and the over molding material, resulting in spring stiffness values that are close to those of the bare diaphragm substrate and damping values that are low enough to have little impact on resonant operation and energy efficiency.

An added advantage of minimizing the over molding material interactions with the spring matrix is that the diaphragm substrate becomes the principal spring stiffness. If the over molding material comprises a significant portion of a composite spring stiffness, made up of the diaphragm substrate stiffness and the over molding material stiffness, then the composite stiffness will change as the over molding material wears and ages. As the stiffness changes the FMD resonant frequency will drift downward resulting in proportionately reduced fluid performance. By minimizing the over molding material interactions with the spring matrix the diaphragm substrate becomes the principal spring stiffness which will remain stable over the life of the product, thereby fixing the FMD resonance frequency and maintaining stable fluid performance. Further, if the over molding material comprises a large portion of the composite stiffness and wears in a non-uniform way, then the diaphragm will become unstable which can lead to excessive FMD noise and vibration.

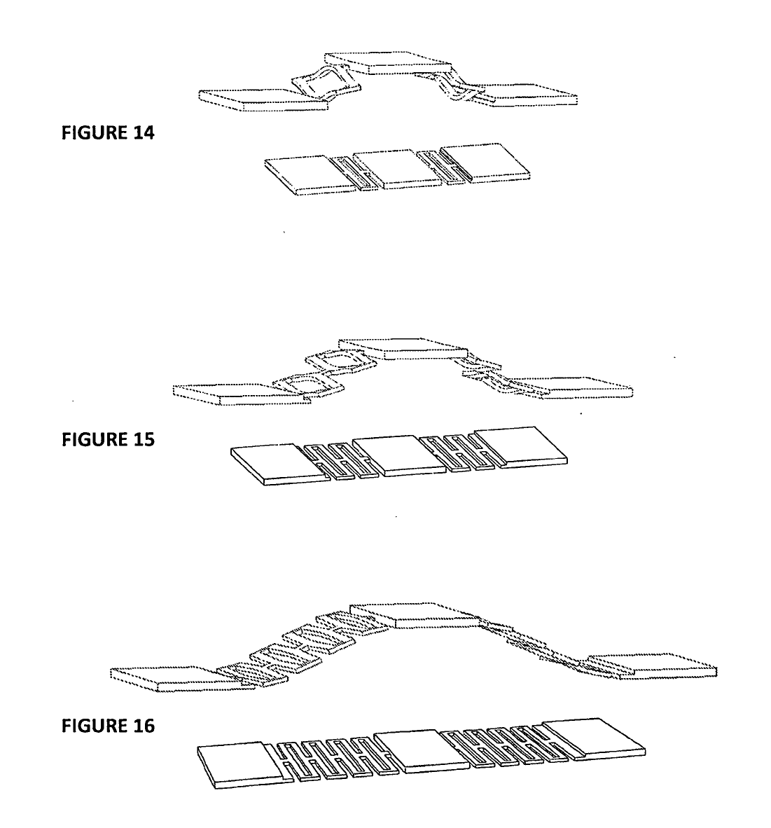

For the types of diaphragms shown in FIGS. 12 and 13 there are three diaphragm design parameters that may be used to achieve principally planar bending: (1) the number of annular spring rows, (2) the number of springs per annular row and (3) the spring leg cross sectional aspect ratio. The effect of the first and second parameters are illustrated in the axial vs. planar bending modes of FIGS. 12 and 13 and are further described in relation to FIGS. 14-16 which show the FEA calculated bending modes of the respective springs. FIGS. 14-16 show a simplified (non axi-symmetric) spring design used to illustrate how adding spring rows causes the bending mode to transition from the predominately axial bending mode of FIG. 14 to the predominately planar bending mode of FIG. 16 as the number of spring rows is increased from two to eight.

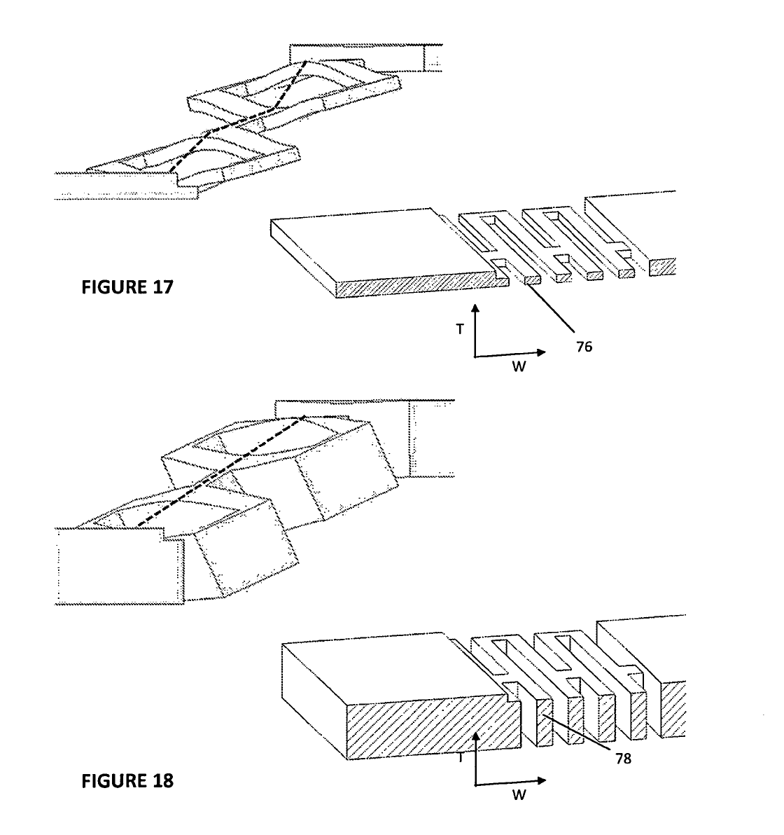

FIGS. 17 and 18 show the spring design of FIG. 15 configured to illustrate the third design parameter. The bending modes shown are calculated using FEA. FIGS. 17 and 18 show cross sectional views of spring legs 76 and 78, respectively, in order to illustrate their spring leg aspect ratios. In FIG. 17, the width W of the spring leg 76 is larger than the thickness T of the spring leg 76 and, in FIG. 18, the thickness T of the spring leg 78 is larger than the width W of the spring leg 78. The change in aspect ratio from FIG. 17 to FIG. 18 is made by changing only the material thickness while all other dimensions remain unchanged. In FIG. 17, where W>T, the bending mode is primarily axial and the black dotted line highlights the bending deviation from a planar mode. In FIG. 18, where T>W, the bending mode is becoming more planar and the black dotted line shows the planar like slope of the spring row center line.

From the above discussion of design parameters it will be clear to one skilled in the art that achieving a planar bending mode is not purely a function of the number of annular spring rows or the number of springs per annular row. Spring leg aspect ratio can also be used to tune a given spring matrix design from principally axial bending to principally planar bending. There are any number of combinations of these design parameters that will enable the degree of planar bending sufficient for a given diaphragm displacement. As such, the scope of the present invention is not limited by a specific diaphragm matrix design nor by the number of individual spring members in the spring matrix. Rather, the scope of the present invention includes the use of principally planar spring matrix bending modes to overcome all of the above-described issues related to pressure sealing a high-stroke high-pressure diaphragm with a flexible sealing material.

Using a single synthetic jet actuator to cool multiple high power devices within a given product requires multi-port manifolds or flexible tubes where each port or tube creates a jet that may be targeted at heat dissipating devices. High power dissipation devices require high velocity pulsating jets whose periodic pressures and air velocities emanating from the jet ports can create sound levels that are too high for a given product's requirements. Excessive noise levels will prevent the significant energy savings associated with synthetic jet multi-port manifold systems from being realized on that product.

The present invention includes a synthetic jet actuator that has two compression chambers whose pumping cycles are 180° out of phase with each other. Jet ports connected to these two compression chambers will produce jet pulses that are also 180° out of phase with each other, resulting in reduced jet noise levels due to cancelation of the two oppositely phased sound sources. In particular the present invention extends the advantages of noise cancelation to the manifolds required to cool multiple hot devices, thereby enabling significant energy savings.

Noise cancelation is less effective if the two oppositely phased sound sources are too far apart. The present invention pairs manifold ports having opposite phases close enough together to maximize noise cancelation. FIG. 6 shows one such embodiment, where manifolds 12 and 14 are connected to respective compression chambers 16 and 18. Compression chambers 16 and 18 are separated by diaphragm 20 for which no drive system or motor is shown for simplicity of illustration. In operation, diaphragm 20 oscillates creating pressure and flow cycles in and out of compression chambers 16 and 20 that are 180° out of phase. Each pair of manifold ports, such as the port pair 22 and 24, will produce air pulses that are 180° out of phase resulting in noise reduction due to cancellation. The cancellation provided by the present invention need not be complete to provide noise reduction, but can have any degree of cancellation from 0% to 100%.

The number of ports of opposite phase need not be equal. As long as the ports of one phase collectively produce a sound power level on the order of the opposite phase ports, cancelation will occur and noise levels will be reduced. The sound power level of a given number of like-phased ports may be varied to match, or be close to, the sound power level of a different number of oppositely phased ports by varying port diameters or by varying characteristics of their respective compression chambers. One approach for varying the compression chamber's output power is to change the total chamber volume so as to vary the compression ratio. If the compression chamber's piston is independent from the oppositely phased compression chamber, then piston stroke may be varied to create matched or nearly matched acoustic power output for the respective group of ports.

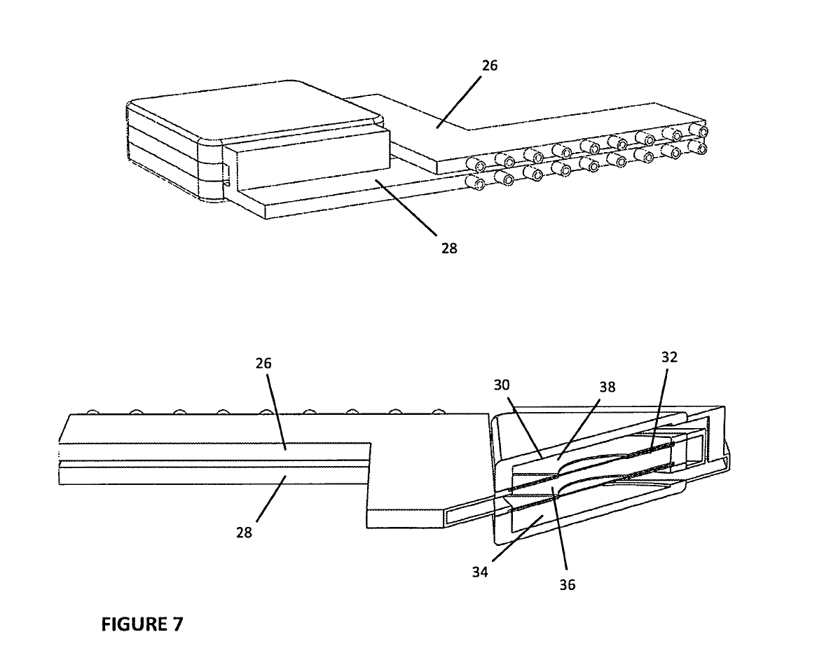

FIG. 7 shows another embodiment of the present invention where compression chambers 30, 32 and 34 are separated by diaphragms 36 and 38. Diaphragms 36 and 38 oscillate 180° out of phase such that the pumping cycles of compression chambers 30 and 34 are 180° out of phase with the pumping cycle of chamber 32. Manifold 26 is attached to compression chamber 32 and manifold 28 is attached to both compression chambers 30 and 34. In operation, when diaphragms 36 and 38 move in opposition, the jet pulses of manifold 26 are 180° out of phase with the jet pulses of manifold 28, which creates cancelation of the sound emitted by the two manifolds. An added advantage of the embodiment of FIG. 7 is that the dynamic reaction forces that diaphragms 36 and 38 exert on the actuator body will cancel, thereby minimizing the actuator's vibration. For simplicity of illustration, no drive system or motor is shown for diaphragms 36 and 38.

The manifolds shown in FIGS. 6 and 7 do have to be two separate parts but could be integrated in to a single part manifold with separate internal conduits for each group of oppositely phase jet ports.

In combining the features of high-displacement high-pressure diaphragms with manifold noise cancelation the present invention enables the use of high power synthetic jet manifold systems for cooling products such as for example servers, computers, routers, laptops, HBLEDs and military electronics.

FIG. 8 discloses an exemplary high-stroke high-pressure diaphragm of the present invention, used in a new low-profile actuator for fluid movers. In FIG. 8, an actuator 48 is comprised of a diaphragm 40 which is shown without over molding for clarity. The diaphragm 40 has a spring matrix 42 and a center section 44 with an electro-active element 46 being bonded to the center section 44. The bonding of the electro-active element 46 to the center section 44 comprises a uni-morph bender actuator.

In operation, the diaphragm 40 serves as the fluid diaphragm of an FMD such as a liquid pump, compressor, vacuum pump or synthetic jet and forms part of a fluid compression chamber. When a voltage is applied to the electro-active material it will expand or contract depending on the polarization of the material and the polarity of the applied voltage. Due to the bond between the electro-active material 46 and the center section 44, the expansion or contraction of electro-active material 46 will cause the composite structure of center section 44 and electro-active material to bend in either a concave or convex shape depending on the polarity of the applied voltage. The actuator 48 will have a mass-spring mechanical resonance whose frequency is determined by the spring stiffness of the spring matrix 42 and the effective axially moving mass comprising the electro-active material 46, the center section 44 and some portion of the spring matrix 42 and its over molding or sealing layer. If an oscillating voltage is applied to the electro-active material 46 whose frequency is near or equal to the mass-spring resonant frequency, then energy will be stored in the mechanical resonance and the diaphragm 40 will oscillate axially thereby providing the positive displacement pumping power of the fluid moving device. The drive voltage frequency can also excite the same mass-spring mechanical resonance by driving at harmonics or sub-harmonics with respective levels of resulting drive efficiency.

FIG. 9 shows one possible enhancement of actuator 48 of FIG. 8. As shown in FIG. 9, a reaction mass 50 is rigidly attached to the center of actuator 48 with fastener 52. The actuator 48 of FIG. 9 is shown with sealing layers 54 which alternatively could be an over molded layer applied with injection molding. In operation, when the bender actuator undergoes bending oscillations, it will push and pull against the reaction mass 50, which in turn creates reaction forces that are applied to diaphragm 40 thereby increasing the force applied to the diaphragm and increasing the efficiency of the actuator. The addition of the reaction mass 50 will also reduce the spring mass resonance frequency of the actuator 48. Any number of differently shaped reaction masses could be used for this purpose and could be located on either or both sides of the actuator. The actuator 48 integrates the functions of motor, fluid diaphragm and system resonance spring all into a single low profile component. This functional integration enables a significant reduction in FMD size without reduction in fluid performance by eliminating the discrete motor, diaphragm and spring components which add to the size of FMDs.

Electrical power leads may be suspended between the electro active material and the fluid mover housing or, alternatively, if the diaphragm 40 is metal then the diaphragm 40 may be used as one electrical power lead and the second lead may be either suspended or bonded to the electrically insulting over molding layer.

The resonance frequency of the actuators of either FIG. 8 or FIG. 9 may be tuned to a desired frequency by designing the cut out geometry and/or the diaphragm thickness to provide a given spring stiffness and by choosing the mass of the reaction mass. Resonant frequencies ranging from mHz to kHz are possible. For example, the actuator could be designed to have a mass-spring mechanical resonance at or near 50 Hz and 60 Hz line frequencies or at sub-harmonics or harmonics of 50 Hz and 60 Hz line frequencies. Various electro active materials may be used such as PZT and the advantages of different electro active materials for a given application will be well known to those skilled in the art.

The foregoing description of some of the embodiments of the present invention have been presented for purposes of illustration and description. The embodiments provided herein are not intended to be exhaustive or to limit the invention to a precise form disclosed, and obviously many modifications and variations are possible in light of the above teaching. The embodiments were chosen and described in order to best explain the principles of the invention and its practical application to thereby enable others skilled in the art to best utilize the invention in various embodiments and with various modifications as are suited to the particular use contemplated. Although the above description contains many specifications, these should not be construed as limitations on the scope of the invention, but rather as an exemplification of alternative embodiments thereof.

What is claimed is:

1. An energy transfer fluid diaphragm comprising:
a diaphragm substrate including cutouts, wherein the cutouts are covered with a sealing layer bonded to the diaphragm substrate, wherein portions of the diaphragm substrate adjacent to the cutouts are configured to bend in a substantially planar mode allowing displacement of a center portion of the diaphragm and wherein the displacement of the center portion transfers energy to a fluid located adjacent to the diaphragm.

2. A liquid pump configured to pump either single-phase or two-phase liquids comprising a positive displacement element for pumping fluid, wherein the positive displacement element comprises the energy transfer fluid diaphragm of claim 1.

3. A compressor or vacuum pump for pumping fluids primarily in a gaseous state, comprising a positive displacement element for pumping fluid, wherein the positive displacement element comprises the energy transfer fluid diaphragm of claim 1.

4. A synthetic jet actuator comprising a positive displacement element for moving fluid, wherein the positive displacement element comprises the energy transfer fluid diaphragm of claim 1.

5. A mechanically resonant fluid mover, comprising a positive displacement element and a system spring for use in a spring-mass mechanical resonance wherein both the positive displacement element and the system spring comprise the energy transfer fluid diaphragm of claim 1.

6. An electro active actuator comprising:
a diaphragm substrate including cutouts, wherein the cutouts are covered with a sealing layer bonded to the diaphragm substrate, and
an electro active material bonded to the center of the diaphragm substrate.

7. The electro active actuator of claim 6 further comprising a reaction mass attached at or near the center of the electro active material.

8. The electro active actuator of claim 6 wherein the diaphragm substrate comprises an electrical lead for applying power to the electro active material.

9. The electro active actuator of claim 8, further comprising a second electrical lead being bonded to the sealing layer, wherein the second electrical lead is electrically isolated from the diaphragm substrate.

10. The electro active actuator of claim 6, wherein the actuator includes a mass-spring mechanical resonance, and wherein the actuator is configured so that a periodic voltage is applied to the electro active material, wherein the voltage is applied at a frequency at or near the mass-spring mechanical resonance of the actuator.

11. The electro active actuator of claim 6, wherein the actuator includes a mass-spring mechanical resonance and wherein the actuator is configured so that a periodic voltage is applied to the electro active material, wherein the voltage is applied at a frequency at or near a sub-harmonic or harmonic of the mass-spring mechanical resonance of the actuator.

12. A fluid energy transfer device comprising:
a diaphragm including a substrate and a sealing layer bonded to the substrate, wherein the substrate includes cutouts and the cutouts are covered by the sealing layer;
a driver for the diaphragm;
wherein a perimeter surface of the diaphragm is connected to a housing to form a chamber between the housing and the diaphragm and where the chamber contains a fluid and the driver is configured to move a central portion of the diaphragm thereby causing a change in the chamber volume whereby the motion of the diaphragm conveys energy to the fluid.

13. A positive displacement liquid pump configured to pump either single-phase or two-phase liquids, comprising the fluid energy transfer device of claim 12, wherein the diaphragm is a positive displacement element for the liquid pump.

14. A compressor or vacuum pump for use with fluids in a primarily gaseous state, comprising the fluid energy transfer device of claim 12, wherein the diaphragm is a positive displacement element for the compressor or vacuum pump.

15. A synthetic jet actuator, comprising the fluid energy transfer device of claim 12, wherein the diaphragm is a positive displacement element for the synthetic jet actuator.

16. A mechanically resonant fluid mover, comprising the fluid energy transfer device of claim 12, wherein the fluid mover includes a positive displacement element and a system spring for use in a spring-mass mechanical resonance wherein both the positive displacement element and the system spring comprise the diaphragm.
